(19) United States
(12) Patent Application Publication
(10) Pub. No.: US 2026/0334239 A1
(43) Pub. Date: Oct. 22, 2026

(54) SEMICONDUCTOR DEVICE

(71) Applicant: SK hynix Inc., Gyeonggi-do (KR)

(72) Inventors: Heon Yong CHANG, Gyeonggi-do (KR); Chi Soung KIM, Gyeonggi-do (KR); Jong Won BAEK, Gyeonggi-do (KR)

(21) Appl. No.: 19/315,660

(22) Filed: Sep. 1, 2025

(30) Foreign Application Priority Data
Apr. 22, 2025 (KR) 10-2025-0052499

(51) Int. Cl. H10W 46/00; H10P 54/00; H10W 42/00

(52) U.S. Cl. CPC H10W 46/00; H10P 54/00; H10W 42/121; H10W 46/503

(57) ABSTRACT

A semiconductor device includes a substrate including a chip region and a scribe lane region formed around the chip region, the scribe lane region including an inner boundary in contact with the chip region, and an outer boundary spaced apart from the inner boundary, a first key region located in the scribe lane region, and spaced apart from the outer boundary of the scribe lane region in a first direction perpendicular to a direction in which the inner boundary of the scribe lane region extends, and a plurality of division-inducing structures, at least one of which is located between the outer boundary of the scribe lane region and the first key region and are arranged along a second direction intersecting the first direction.

### CROSS REFERENCE TO RELATED APPLICATION

The present application claims priority under 35 U.S.C. 119(a) to Korean patent application number 10-2025-0052499 filed on Apr. 22, 2025, which is incorporated herein by reference in its entirety.

### BACKGROUND

### 1. Technical Field

Various embodiments of the present disclosure relate to a semiconductor device.

### 2. Related Art

As semiconductor devices become highly integrated, the semiconductor devices may be fabricated on a single wafer and then separated through a cutting process such as sawing or dicing.

As the high integration of semiconductor devices progresses, the cutting process for semiconductor devices faces technical difficulties. For example, various keys such as alignment keys may typically be located at positions where a cutting line passes, which may cause separation defects around regions where the keys are located during the cutting process.

### SUMMARY

The embodiments of the present disclosure are not limited to the embodiments described herein, and other embodiments that are not described will be clearly understood by a person skilled in the art from the description below.

Various embodiments of the present disclosure are directed to a semiconductor device capable of minimizing defects that occur during a cutting process.

According to some embodiments of the present disclosure, a semiconductor device may include a substrate including a chip region and a scribe lane region formed around the chip region, the scribe lane region including an inner boundary in contact with the chip region, and an outer boundary spaced apart from the inner boundary, a first key region located in the scribe lane region, and spaced apart from the outer boundary of the scribe lane region in a first direction perpendicular to a direction in which the inner boundary of the scribe lane region extends, and a plurality of division-inducing structures, at least one of which is located between the outer boundary of the scribe lane region and the first key region and are arranged along a second direction intersecting the first direction.

In some embodiments of the present disclosure, a semiconductor device may include a substrate including a chip region and a scribe lane region formed around the chip region, the scribe lane region including an inner boundary in contact with the chip region, and an outer boundary spaced apart from the inner boundary, a first key region located in the scribe lane region, and spaced apart from the outer boundary in a first direction perpendicular to a direction in which the inner boundary extends, a second key region spaced apart from the first key region in a second direction intersecting the first direction, and division-inducing structures arranged between the outer boundary and the first key region, or between the first key region and the second key region, or between the outer boundary and the first key region and between the first key region and the second key region.

In some embodiments of the present disclosure, a semiconductor device may include a substrate including a chip region and a scribe lane region formed around the chip region, a first key region located in the scribe lane region, and including a first boundary facing the chip region, and a second boundary oriented parallel to the first boundary and spaced apart from the first boundary in a first direction perpendicular to a direction in which the first boundary extends, and division-inducing structures located outside the second boundary in the first direction.

In some embodiments of the present disclosure, a semiconductor device may include a substrate including a scribe lane region adjacent to a chip region, a first key region located in the scribe lane region including a first key group, a second key region spaced apart from the first key region and a plurality of division-inducing structures spaced apart from each other in a region between the first key region and the second key region, wherein a length of each of the division-inducing structures in a second direction is greater than a length of in the first direction, and wherein at least one of the division-inducing structures face the first key group in the first direction.

Various embodiments of the present disclosure may provide a semiconductor device capable of minimizing defects that occur during a cutting process.

The advantageous effects of various embodiments are not limited only to those specifically mentioned here, and it should be understood that other advantageous effects not specifically described may also be understood by those with ordinary skill in the art from the scope of present disclosure and the appended claims.

### BRIEF DESCRIPTION OF THE DRAWINGS

The embodiments of the present disclosure will be more fully understood from the following detailed description and the accompanying drawings. The description and the drawings are provided for illustrative purposes only and are not intended to limit the scope of the present disclosure to the described embodiments.

FIG. 1 is a view illustrating a planar structure of a semiconductor device according to some embodiments of the present disclosure.

FIG. 2 is a view illustrating a cross-sectional structure taken along line I-I’ of FIG. 1.

FIG. 3 is a view illustrating a cross-sectional structure taken along line II-II’ of FIG. 1.

FIGS. 4-6 are views illustrating other planar structures of the semiconductor device according to some embodiments of the present disclosure.

FIG. 7 is a view illustrating a cross-sectional structure taken along line III-III’ of FIG. 6.

FIGS. 8 and 9 are views illustrating other planar structures of the semiconductor device according to some embodiments of the present disclosure.

### DETAILED DESCRIPTION

Hereinafter, various embodiments of the present disclosure will be described in detail with reference to the accompanying drawings. In the following description, like reference numerals may be used to designate the same components although the components are shown in different drawings. Furthermore, in the following description, a detailed description of known functions and configurations incorporated herein will be omitted to avoid obfuscating the present disclosure. Terms such as “including,” “having,” and “comprising” used herein are generally intended to allow other components to be added unless the terms are used with the term “only”. Any references to singular may include plural unless expressly stated otherwise.

Also, in describing the components of the disclosure, there may be terms used like first, second, A, B, (a), and (b). These are solely for the purpose of differentiating one component from the other and do not imply or suggest the substances, order, sequence or number of the components.

In descriptions for positional relationships of components, in the case where it is described that at least two components are “connected,” “coupled” or “linked,” it is to be understood that the at least two components may be directly “connected,” “coupled” or “linked” but may also be indirectly “connected,” “coupled” or “linked” with another component “interposed” between the two components. Further, another component may be included in at least one of the at least two components which are “connected,” “coupled” or “linked” with each other.

In descriptions for time flow relationships of components, an operating method or a fabricating method, in the case where pre and post relationships in terms of time or pre and post relationships in terms of flow are described, for example, by “after,” “following,” “next” or “before,” non-continuous cases may be included unless “immediately” or “directly” is used.

In the case where a numerical value for a component or its corresponding information (e.g., level, etc.) is mentioned, even though there is no separate explicit description, the numerical value or its corresponding information can be interpreted as including an error range that may be caused by various factors (for example, a process variable, an internal or external shock, noise, etc.).

Hereinafter, various embodiments of the present disclosure will be described in detail with reference to the accompanying drawings.

In the accompanying drawings, two directions on an upper surface of a substrate 200 are defined as a first direction FD and a second direction SD, respectively, and a direction protruding perpendicularly from the upper surface of the substrate 200 is defined as a third direction VD. The first direction FD and the second direction SD may be substantially perpendicular to each other. The third direction VD is perpendicular to both the first direction FD and the second direction SD. In the following description, the terms “perpendicular” or “perpendicular direction” are used to mean substantially the same as the third direction VD. In the drawings, a direction indicated by an arrow and the opposite direction thereof represent the same direction.

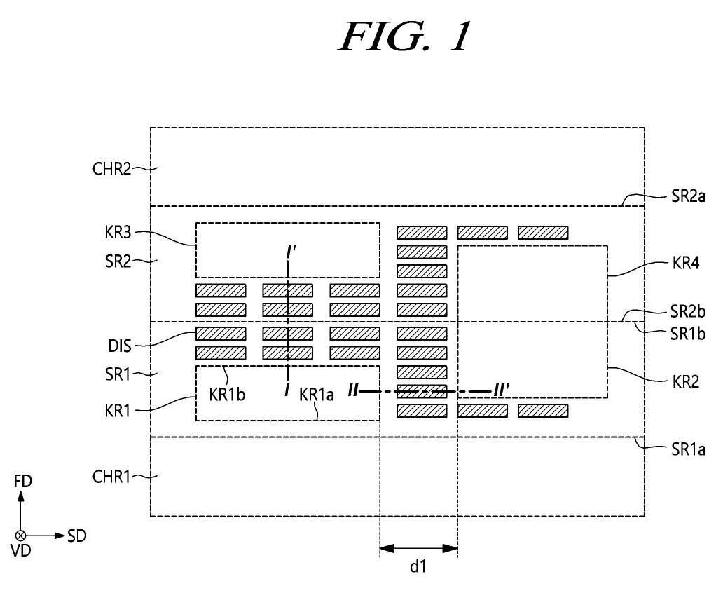

FIG. 1 is a view illustrating a planar structure of a semiconductor device according to some embodiments of the present disclosure. FIG. 1 illustrates a state in which a plurality of semiconductor devices are formed on a single wafer before they are separated into individual chips.

Referring to FIG. 1, a first chip region CHR1 and a second chip region CHR2 are spaced apart from each other. The first and second chip regions CHR1 and CHR2 may each refer to a region in which elements and wires constituting a single semiconductor device are located. For example, elements and wires that are located in the first chip region CHR1 form a first semiconductor device different from the elements and wires located in the second chip region CHR2 which form a second semiconductor device.

A first scribe lane region SR1 is located around the first chip region CHR1. A second scribe lane region SR2 is located around the second chip region CHR2. In the illustrated embodiment of FIG. 1, the second scribe lane region SR2 may be continuous with the first scribe lane region SR1. In another embodiment (not shown), the first and second scribe lane regions SR1 and SR2 may be separated from each other by a cutting process. The first and second scribe lane regions SR1 and SR2 may belong to different semiconductor devices.

The first scribe lane region SR1 may include a first inner boundary SR1a and a first outer boundary SR1b. The second scribe lane region SR2 may include a second inner boundary SR2a and a second outer boundary SR2b. The first inner boundary SR1a refers to a boundary between the first chip region CHR1 and the first scribe lane region SR1. The first inner boundary SR1a may contact the first chip region CHR1. The first outer boundary SR1b may be spaced apart from the first inner boundary SR1a in the first direction FD. The first outer boundary SR1b refers to a boundary between the first and second scribe lane regions SR1 and SR2. The first outer boundary SR1b may refer to the same boundary as the second outer boundary SR2b. The first outer boundary SR1b and the second outer boundary SR2b may each refer to an outermost boundary of a different semiconductor device.

In some embodiments, the first chip region CHR1 and the first scribe lane region SR1 are included in a single semiconductor device (e.g., a first semiconductor device). The second chip region CHR2 and the second scribe lane region SR2 may be included in a semiconductor device different from the first semiconductor device (e.g., a second semiconductor device).

Hereinafter, for convenience of description, the semiconductor device may be described and is referred to as the first semiconductor device. Since, the second semiconductor device is the same or substantially the same as the first semiconductor device, the following description focuses on the first semiconductor device.

A first key region KR1 and a second key region KR2 may be located in the first scribe lane region SR1. A third key region KR3 and a fourth key region KR4 may be located in the second scribe lane region SR2. The first key region KR1, the second key region KR2, the third key region KR3, and the fourth key region KR4 may refer to regions in which various keys such as, for example, an alignment key, an overlay key, or combinations thereof are arranged. In some embodiments, at least one overlay key may be located in each of the key regions, i.e., in each of the first, second, third, and fourth key regions KR1, KR2, KR3, and KR4.

The first key region KR1 may be spaced apart from the first outer boundary SR1b of the first scribe lane region SR1 in the first direction FD. In some embodiments, no key is located between the first key region KR1 and the first outer boundary SR1b. The first key region KR1 may include a first boundary KR1a and a second boundary KR1b. The first boundary KR1a of the first key region KR1 may be a boundary facing the first chip region CHR1. The first boundary KR1a of the first key region KR1 may be spaced apart from the first chip region CHR1. The second boundary KR1b may be spaced apart from the first boundary KR1a in the first direction FD. The second boundary KR1b may be spaced apart from the first outer boundary SR1b of the first scribe lane region SR1 in the first direction FD.

The second key region KR2 may contact the first outer boundary SR1b. One side of the second key region KR2 may contact the first outer boundary SR1b. The second key region KR2 may overlap with a region between the first outer boundary SR1b and the second boundary KR1b in the second direction SD. In some embodiments, the second key region KR2 is spaced apart from the first key region KR1 in the second direction SD. In some embodiments, a first spacing distance d1 between the second key region KR2 and the first key region KR1 may be 5 µm or greater. In the case where the first spacing distance d1 between the second key region KR2 and the first key region KR1 is 5 µm or less, a region formed to place a division-inducing structure DIS, which is described below, may not be secured. The division-inducing structure may ensure effective separation or partitioning within the device, making sufficient spacing for its functionality.

The division-inducing structure DIS may be located in the first scribe lane region SR1. In some embodiments, the division-inducing structure DIS is located between the first key region KR1 and the first outer boundary SR1b of the first scribe lane region SR1. The division-inducing structure DIS may be located further outward from the second boundary KR1b of the first key region KR1. The division-inducing structure DIS may overlap with the first key region KR1 in the first direction FD. In some embodiments, as illustrated in FIG. 1, in the first direction FD, the first key region KR1 may overlap with three division-inducing structures DIS arranged in the second direction SD. However, the number of division-inducing structures DIS that overlap with the first key region KR1 is provided as an example and may not limited thereto.

In some embodiments, division-inducing structures DIS may overlap with the second key region KR2 in the second direction SD. In some embodiments, division-inducing structures DIS are located between the first key region KR1 and the second key region KR2 in the second direction SD. In some embodiments, division-inducing structures DIS are arranged along respective edges of the first key region KR1 and the second key region KR2. In some embodiments, in the second direction SD, the second key region KR2 may overlap with one or more division-inducing structures DIS arranged in the first direction FD.

In some embodiments, the division-inducing structures DIS may be arranged along a direction through which a division line passes. For example, the division-inducing structures DIS may be arranged along the second direction SD. In some embodiments, the division-inducing structures DIS may be located at positions which are spaced apart from each other in the first direction FD and the second direction SD.

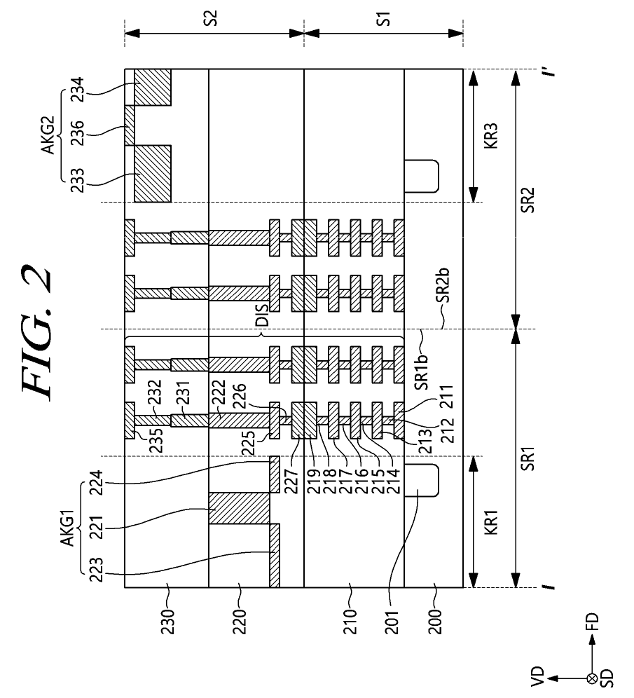

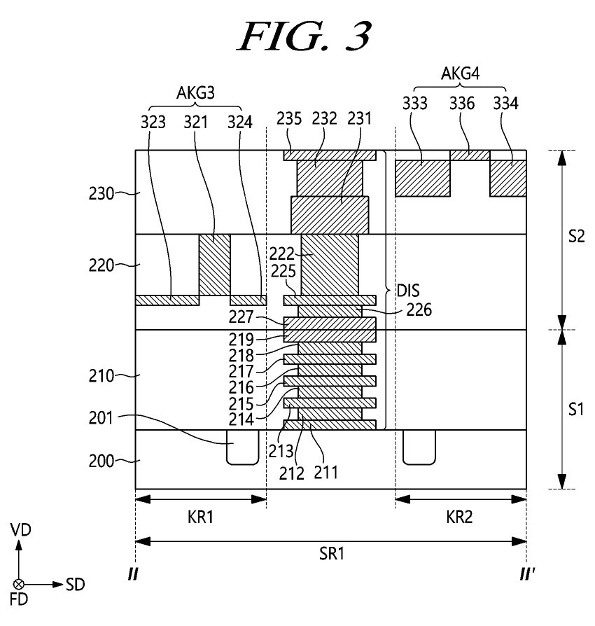

FIG. 2 illustrates a cross-sectional structure taken along line I-I’ of FIG. 1. FIG. 3 illustrates a cross-sectional structure taken along line II-II’ of FIG. 1.

Referring to FIGS. 2 and 3, the first semiconductor device may include a first semiconductor structure S1, a second semiconductor structure S2, and division-inducing structures DIS.

The first semiconductor structure S1 may include a substrate 200, a first element isolation layer 201, and a first insulating layer 210 disposed on the substrate 200. The second semiconductor structure S2 may include a second insulating layer 220, a first key group AKG1, a third key group AKG3, and a third insulating layer 230. The first key group AKG1 may include a first key segment 221, a second key segment 223, and a third key segment 224. In some embodiments, The first key segment 221 may be disposed between the second and third key segments 223 and 224 in the first direction FD but may not overlap with either the second or the third key segment 223 and 224 in the first direction FD. The second and third segments 223 and 224 may overlap with each other in the first direction FD. The first key segment 221 may have a lower surface that is at same level with the upper surfaces of the second and third key segments 223 and 224. The first key segment 221 may have an upper surface that is at same level as the boundary between the second insulating layer 220 and the third insulating layer 230. The third key group AKG3 may include a fourth key segment 321, a fifth key segment 323, and a sixth key segment 324. Each of the division-inducing structures DIS may include a first conductive layer 211, a first contact 212, a second conductive layer 213, a second contact 214, a third conductive layer 215, a third contact 216, a fourth conductive layer 217, a fourth contact 218, a first bonding pad 219, a fifth contact 222, a fifth conductive layer 225, a sixth contact 226, a second bonding pad 227, a seventh contact 231, an eighth contact 232, and a sixth conductive layer 235.

The second semiconductor device may include a second key group AKG2 and a fourth key group AKG4. The second key group AKG2 may include a seventh key segment 233, an eighth key segment 234, and a ninth key segment 236. The fourth key group AKG4 may include a tenth key segment 333, an eleventh key segment 334, and a twelfth key segment 336.

The first key group AKG1 and the third key group AKG3 may be located in the first key region KR1. In some embodiments, the first key group AKG1 and the third key group AKG3 may include overlay keys. The first key segment 221, the second key segment 223, the third key segment 224, the fourth key segment 321, the fifth key segment 323, and the sixth key segment 324 may constitute some or the entirety of the overlay keys.

The first key group AKG1 may be spaced apart from the first outer boundary SR1b of the first scribe lane region SR1 in the first direction FD.

At least one division-inducing structure DIS may be located between the first key region KR1 and the first outer boundary SR1b of the first scribe lane region SR1 in the first direction FD.

In some embodiments, the division-inducing structure DIS may be physically separated from the first key group AKG1 and the third key group AKG3. In some embodiments, the division-inducing structure DIS may electrically float meaning it is not directly connected to a fixed reference potential. Instead, its potential may vary dynamically depending on surrounding electrical conditions, which can influence the behavior of the semiconductor device.

In some embodiments, the division-inducing structure DIS may penetrate at least a portion of each of the first and second semiconductor structures S1 and S2. For example, the division-inducing structure DIS may completely penetrate the second semiconductor structure S2 and may be connected to the substrate 200 of the first semiconductor structure S1. In some embodiments, an upper surface of the division-inducing structure DIS, that is, an upper surface of the sixth conductive layer 235, may be flush or substantially flush with an upper surface of the second semiconductor structure S2.

In some embodiments, the division-inducing structure DIS may penetrate an interface between the first semiconductor structure S1 and the second semiconductor structure S2. In some embodiments, a portion of the division-inducing structure DIS that belongs to the first semiconductor structure S1 and a portion of the division-inducing structure DIS that belongs to the second semiconductor structure S2 may be bonded to each other. For example, the first bonding pad 219 and the second bonding pad 227 included in the division-inducing structure DIS are bonded to each other. An upper surface of the first bonding pad 219 may be flush or substantially flush with an upper surface of the first semiconductor structure S1. A lower surface of the second bonding pad 227 may be flush or substantially flush with a lower surface of the second semiconductor structure S2.

In some embodiments, the division-inducing structure DIS may overlap with the first key group AKG1 and the third key group AKG3 in the first direction FD. For example, the second key segment 223 and the third key segment 224 may be located in the same layer as the fifth conductive layer 225. For instance, the first key segment 221 may be located in the same layer as the fifth contact 222. In some embodiments, the fifth conductive layer 225 is formed together with the second key segment 223 and the third key segment 224 in an operation of forming the second key segment 223 and the third key segment 224. In some embodiments, the fifth contact 222 is formed together with the first key segment 221 in an operation of forming the first key segment 221.

In some embodiments, a distance from the upper surface of the division-inducing structure DIS to the substrate 200 is greater than a distance from an upper surface of the first key group AKG1 to the substrate 200. The distance from the upper surface of the division-inducing structure DIS to the substrate 200 may be substantially equal to a distance from an upper surface of the second key group AKG2 to the substrate 200.

Each of the first key segment 221, the second key segment 223, the third key segment 224, the first conductive layer 211, the first contact 212, the second conductive layer 213, the second contact 214, the third conductive layer 215, the third contact 216, the fourth conductive layer 217, the fourth contact 218, the first bonding pad 219, the fifth contact 222, the fifth conductive layer 225, the sixth contact 226, the second bonding pad 227, the seventh contact 231, the eighth contact 232, and the sixth conductive layer 235 may include a conductive material such as, for example, metal, metal oxide, metal nitride, metal silicide, polysilicon, conductive carbon, or a combination thereof.

In some embodiments, the division-inducing structures DIS may function to guide a division line during the cutting process of the semiconductor device. This is described in more detail below.

During the cutting process, a division line may pass along the first outer boundary SR1b of the first scribe lane region SR1 or along a region adjacent to the first outer boundary SR1b. In the case where the division line passes along the region adjacent to the first outer boundary SR1b, the division line may bypass the division-inducing structures DIS that are relatively hard. For example, the division line may pass along a space between the division-inducing structures DIS in the second direction SD. A position at which the division line passes may vary depending on the lengths of the division-inducing structures DIS in the first direction FD or the second direction SD, a distance between the division-inducing structures DIS, an arrangement pattern thereof, or the like.

As shown in FIG. 1, when the division-inducing structures DIS are arranged along the second direction SD between the first outer boundary SR1b and the first key region KR1, the division line may pass along the spaces between the division-inducing structures DIS in the second direction SD. Accordingly, the propagation of the division line into the first key region KR1 or the first chip region CHR1 may be prevented. As a result, various process defects that may occur during the cutting process may be prevented or minimized.

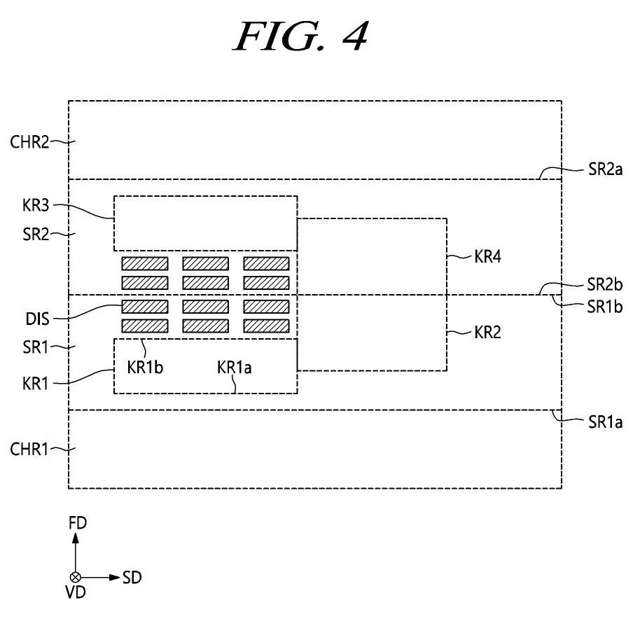

FIGS. 4-6 are views illustrating other planar structures of the semiconductor device according to some embodiments of the present disclosure.

Referring to FIG. 4, the first key region KR1 may be spaced apart from the first outer boundary SR1b of the first scribe lane region SR1 in the first direction FD. The first key region KR1 may include a first boundary KR1a and a second boundary KR1b. The second boundary KR1b may be spaced apart from the first boundary KR1a in the first direction FD. The first boundary KR1a may be spaced apart from the first chip region CHR1. The second boundary KR1b may also be spaced apart from the first outer boundary SR1b of the first scribe lane region SR1 in the first direction FD.

The second key region KR2 may contact the first outer boundary SR1b, meaning that one side of the second key region KR2 may contact the first outer boundary SR1b. The second key region KR2 may overlap with a region between the first outer boundary SR1b and the second boundary KR1b in the second direction SD. The second key region KR2 may be spaced apart from the first inner boundary SR1a of the first scribe lane region SR1.

In some embodiments, the second key region KR2 may contact the first key region KR1. The first key region KR1 and the second key region KR2 may enclose the division-inducing structures DIS. No division-inducing structure DIS may be located between the first key region KR1 and the second key region KR2.

The division-inducing structures DIS may be located between the first key region KR1 and the first outer boundary SR1b of the first scribe lane region SR1. The division-inducing structures DIS may be located further outward from the second boundary KR1b of the first key region KR1. The division-inducing structures DIS may overlap with the first key region KR1 in the first direction FD. The division-inducing structures DIS may overlap with the second key region KR2 in the second direction SD.

In some embodiments, the division-inducing structures DIS may be arranged along a direction in which a division line passes. For example, the division-inducing structures DIS may be arranged along the second direction SD. In some embodiments, the division-inducing structures DIS may be arranged at positions which are spaced apart from each other in the first direction FD and the second direction SD.

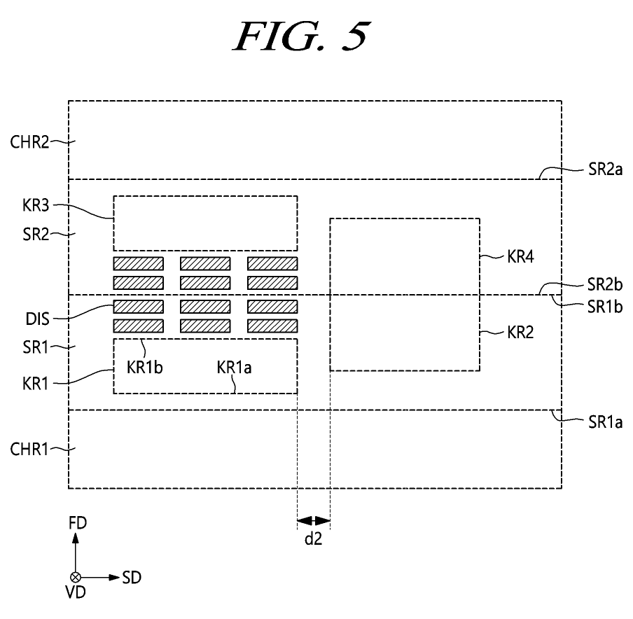

Referring now to FIG. 5, the second key region KR2 may be spaced apart from the first key region KR1 in the second direction SD. In some embodiments, as illustrated in FIG. 5, no division-inducing structure DIS may be located in the region between the second key region KR2 and the first key region KR1. The region between the second key region KR2 and the first key region KR1 may be free of any division-inducing structures DIS.

In the embodiment of FIG. 5, a second spacing distance d2 between the second key region KR2 and the first key region KR1 in the second direction SD is smaller than the first spacing distance d1 of the embodiment of FIG. 1 between the second key region KR2 and the first key region KR1 in the second direction SD. For example, the second spacing distance d2 between the second key region KR2 and the first key region KR1 may be equal to or less than 5 μm.

As described above with reference to FIGS. 4 and 5, no division-inducing structure DIS may be disposed between the first key region KR1 and the second key region KR2, and the distance between first key region KR1 and second key region KR2 may be smaller than the first spacing distance d1 described with reference to FIG. 1. In this case, a region in which keys are arranged may be reduced. In some embodiments, in the case where the region in which keys are arranged is reduced, a region in the first scribe lane region SR1, where components other than the keys (for example, a trench provided in the scribe lane region to improve division linearity) can be disposed, has a relatively larger area. Accordingly, the first scribe lane region SR1 may be efficiently used.

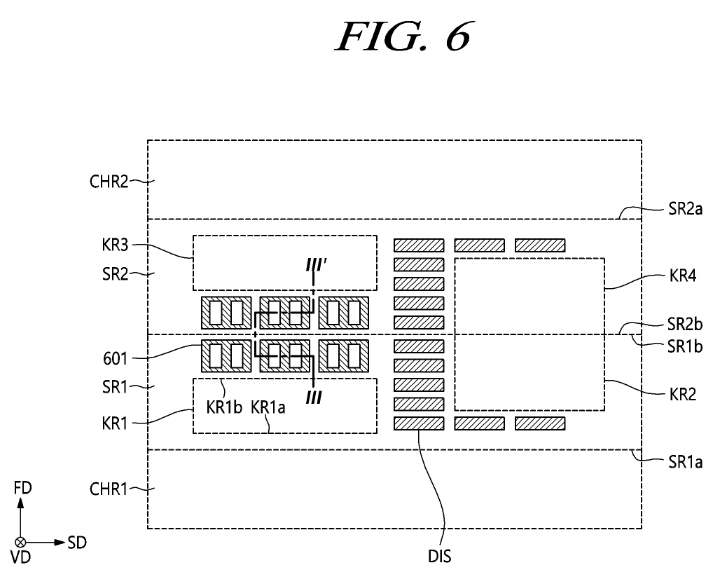

Referring to FIG. 6, the first key region KR1 may be spaced apart from the first outer boundary SR1b of the first scribe lane region SR1 in the first direction FD. The first key region KR1 may include a first boundary KR1a and a second boundary KR1b spaced apart from each other in the first direction FD. The second boundary KR1b may be spaced apart from the first outer boundary SR1b of the first scribe lane region SR1 in the first direction FD.

The second key region KR2 may contact the first outer boundary SR1b, meaning that one side of the second key region KR2 may contact the first outer boundary SR1b. The second key region KR2 may overlap with a region between the first outer boundary SR1b and the second boundary KR1b in the second direction SD. In some embodiments, the second key region KR2 may be spaced apart from the first key region KR1 in the second direction SD.

A plurality of dummy gate electrodes 601 may be disposed between the first key region KR1 and the first outer boundary SR1b of the first scribe lane region SR1. The dummy gate electrodes 601 may be arranged at positions which are spaced apart from each other in the first direction FD and the second direction SD. In some embodiments, the dummy gate electrodes 601 may be arranged along the second direction SD. Although FIG. 6 illustrates that three dummy gate electrodes 601 are arranged between the first key group AKG1 and the first outer boundary SR1b, the number of dummy gate electrodes 601 is not limited thereto.

The second key region KR2 may overlap with a region in which the dummy gate electrode 601 is located in the second direction SD. At least one division-inducing structure DIS may be located between the first key region KR1 and the second key region KR2. In some embodiments, as illustrated in FIG. 6, division-inducing structures DIS may also be arranged along an edge of the second key region KR2. For example, FIG. 6 illustrates that two division-inducing structures DIS are positioned between the second key region KR2 and the first chip region CHR1.

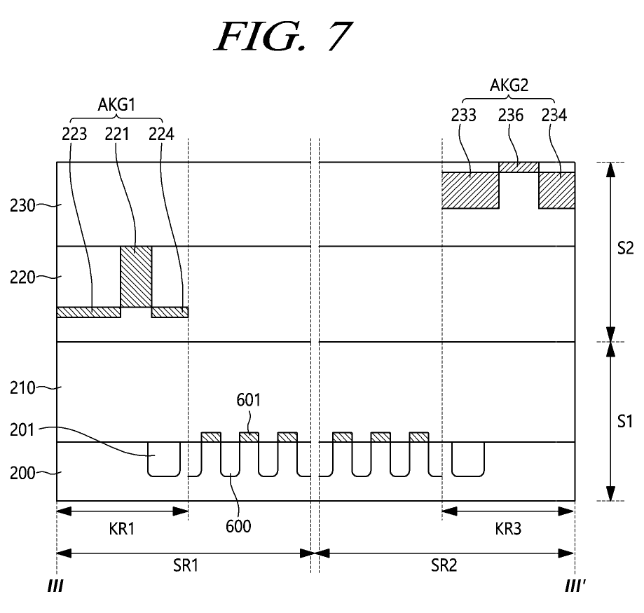

FIG. 7 illustrates a cross-sectional structure along line III-III’ of FIG. 6.

Referring to FIG. 7, the first semiconductor device may include a first semiconductor structure S1 and a second semiconductor structure S2.

The first semiconductor structure S1 may include a substrate 200, a first element isolation layer 201, a second element isolation layer 600, a dummy gate electrode 601, and a first insulating layer 210. The second semiconductor structure S2 may include a second insulating layer 220, a first key group AKG1, and a third insulating layer 230. The first key group AKG1 may include a first key segment 221, a second key segment 223, and a third key segment 224.

The second semiconductor device S2 may include a second key group AKG2. The second key group AKG2 may include a seventh key segment 233, an eighth key segment 234, and a ninth key segment 236.

Referring to FIGS. 6 and 7, The first key group AKG1 may be located in the first key region KR1 and may be spaced apart from the first outer boundary SR1b of the first scribe lane region SR1 in the first direction FD. The first key group AKG1 may be substantially the same as the first key group AKG1 described with reference to FIG. 2.

At least one dummy gate electrode 601 may be located between the first key group AKG1 and the first outer boundary SR1b of the first scribe lane region SR1 in the first direction FD.

Referring to FIGS. 6 and 7, in a region where each dummy gate electrode 601 is located, the second element isolation layer 600 may be located in a region that does not overlap with the dummy gate electrode 601. Furthermore, each second element isolation layer 600 may be located between consecutive dummy gate electrodes 601 in the second direction SD. The second element isolation layer 600 may extend in the first direction FD. The second element isolation layer 600 may be spaced apart from the first outer boundary SR1b of the first scribe lane region SR1 in the first direction FD.

In some embodiments, the dummy gate electrodes 601 may be physically separated from the first key group AKG1. In some embodiments, the dummy gate electrodes 601 may electrically float.

In some embodiments, the dummy gate electrodes 601 do not overlap with the first key group AKG1 in the first direction FD. The dummy gate electrodes 601 may be spaced apart from the second semiconductor structure S2 in a vertical direction.

The dummy gate electrodes 601 may include a conductive material such as, for example, metal, metal oxide, metal nitride, metal silicide, polysilicon, conductive carbon, or a combination thereof. The second element isolation layer 600 may include silicon oxide, silicon nitride, silicon oxynitride, a high-k dielectric, or a combination thereof.

The division-inducing structure DIS may be arranged between the first key region KR1 and the second key region KR2. In some embodiments, the division-inducing structures DIS may be located between the first key region KR1 and the second key region KR2 in the second direction SD. In some embodiments, the division-inducing structures DIS may be arranged along the edge of the second key region KR2. No division-inducing structure DIS may be disposed between the first key region KR1 and the first outer boundary SR1b of the first scribe lane region SR1.

In some embodiments, a division line passes along a region adjacent to the first outer boundary SR1b during the cutting process. Importantly, this way the division line does not pass through a region in which the dummy gate electrode 601 and the second element isolation layer 600 are located. In this manner, the dummy gate electrode 601 and the second element isolation layer 600 may function to block the division line from propagating into the first key region KR1 along the first direction FD. Accordingly, division may occur only in the region adjacent to the first outer boundary SR1b. The division may mainly occur in a region between the first outer boundary SR1b and the dummy gate electrodes 601 adjacent to the first outer boundary SR1b. Therefore, various process defects that may occur during the cutting process can be prevented or minimized.

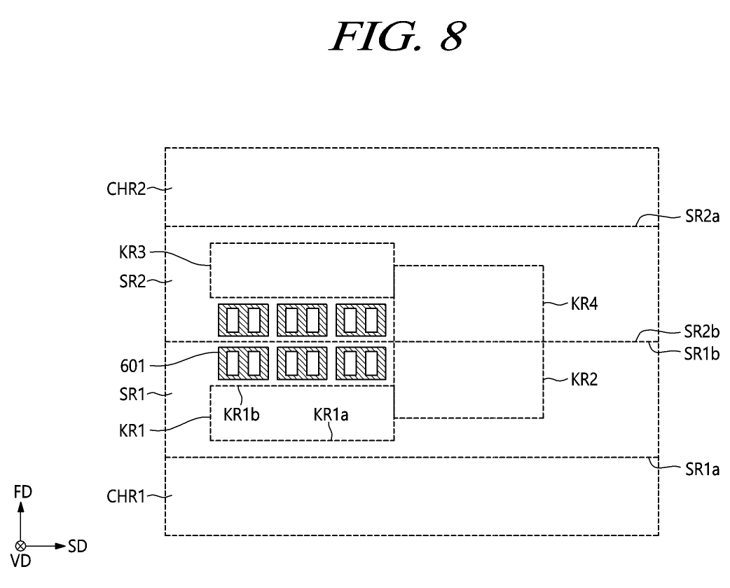

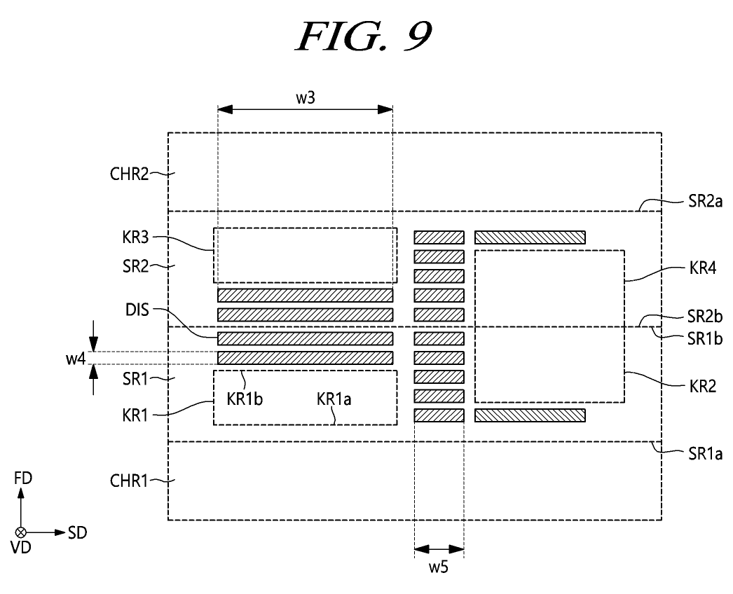

FIGS. 8 and 9 are views illustrating other planar structures of the semiconductor device according to some embodiments of the present disclosure.

Referring to FIG. 8, the first key region KR1 may be spaced apart from the first outer boundary SR1b of the first scribe lane region SR1 in the first direction FD. The first key region KR1 may include a first boundary KR1a and a second boundary KR1b spaced apart from each other in the first direction FD. The second boundary KR1b may be spaced apart from the first outer boundary SR1b of the first scribe lane region SR1 in the first direction FD.

The second key region KR2 may contact the first outer boundary SR1b, meaning the one side of the second key region KR2 may contact the first outer boundary SR1b. The second key region KR2 may overlap with a region between the first outer boundary SR1b and the second boundary KR1b in the second direction SD.

In some embodiments, as illustrated in FIG. 8, the second key region KR2 may contact the first key region KR1. The first key region KR1 and the second key region KR2 may enclose the dummy gate electrodes 601. No dummy gate electrode 601 may be disposed between the first key region KR1 and the second key region KR2.

The dummy gate electrodes 601 may be arranged between the first key region KR1 and the first outer boundary SR1b of the first scribe lane region SR1. The dummy gate electrodes 601 may be located further outward from the second boundary KR1b of the first key region KR1. The dummy gate electrodes 601 may overlap with the first key region KR1 in the first direction FD. In some embodiments, the dummy gate electrodes 601 may overlap with the second key region KR2 in the second direction SD.

In some embodiments, the dummy gate electrodes 601 may be arranged along a direction through which a division line passes. For example, the dummy gate electrodes 601 may be arranged along the second direction SD. In some embodiments, the dummy gate electrodes 601 may be located at positions which are spaced apart from each other in the first direction FD and the second direction SD.

As described above with reference to FIG. 8, no dummy gate electrode 601 may be located between the first key region KR1 and the second key region KR2. The region between the first key region KR1 and the second key region KR2 may be free of any dummy gate electrodes 601. In this case, the size of the region in which keys are disposed may be reduced. Accordingly, a region in the first scribe lane region SR1, where components other than the keys (for example, a trench provided to improve division linearity in the scribe lane region) may be arranged, may have a relatively larger area. Therefore, the first scribe lane region SR1 may be utilized more efficiently.

Referring to FIG. 9, division-inducing structures DIS may be located between the first key region KR1 and the first outer boundary SR1b of the first scribe lane region SR1. The division-inducing structures DIS may be located between the first key region KR1 and the second key region KR2. In some embodiments, the division-inducing structures DIS may also be arranged along edges of the first key region KR1 and the second key region KR2. For example, in the embodiment of FIG. 9, division-inducing structures DIS are positioned between the first key region KR1 and the second key region KR2, also between the second key region KR2 and the first chip region CHR1, also between the first key region KR1 and the first outer boundary SR1b of the first scribe lane region SR1.

In some embodiments, the division-inducing structures DIS may be arranged in a direction in which the division line passes. In some embodiments, the division-inducing structures DIS may be arranged in the second direction SD.

In some embodiments, the division-inducing structures DIS are located at positions which are spaced apart from each other in the first direction FD.

In some embodiments, in the first direction FD, the first key region KR1 may overlap with each division-inducing structure DIS oriented in the second direction SD. In the second direction SD, the second key region KR2 may overlap two division-inducing structures DIS arranged in the first direction FD. The number of division-inducing structures DIS arranged in the first direction FD is not limited thereto.

In some embodiments, a width w3 of the division-inducing structure DIS in the second direction SD, which is located between the first outer boundary SR1b and the first key region KR1, may be wider than a width w4 of each division-inducing structure DIS in the first direction FD, which is located between the first outer boundary SR1b and the first key region KR1. In some embodiments, the width w3 of the division-inducing structure DIS in the second direction SD, which is located between the first outer boundary SR1b and the first key region KR1, may be wider than a width w5 of each division-inducing structure DIS in the second direction SD, which is located between the first key region KR1 and the second key region KR2.

In the case where a division line passes along a region near the first outer boundary SR1b during the cutting process, the division line may bypass the division-inducing structures DIS, which are relatively hard. That is, the division line may pass through a region between the division-inducing structures DIS. As described above, the width of each division-inducing structure DIS in the second direction SD, which is located between the first outer boundary SR1b and the first key region KR1, may be wider than the width of the division-inducing structure DIS in the first direction FD. In addition, in the first direction FD, the first key region KR1 may overlap one division-inducing structure DIS arranged in the second direction SD. Accordingly, during the cutting process, propagation of the division line into the first key region KR1 or the first chip region CHR1 along the first direction FD may be more effectively prevented. Therefore, various process defects that may occur during the cutting process may be prevented or minimized.

The above description is merely illustrative of the technical spirit of the present disclosure, and various modifications and changes may be made thereto by those skilled in the art without departing from the essential characteristics of the present disclosure. Furthermore, various embodiments are not intended to limit the technical idea of the present disclosure but to illustrate the technical idea of the present disclosure, and the technical idea of the present disclosure is not limited by these embodiments. The scope of the disclosure shall be construed based on the accompanying claims in such a manner that all the technical ideas included within the scope equivalent to the claims belong to the present disclosure. Furthermore, the embodiments may be combined to form additional embodiments.

What is claimed is:

1. A semiconductor device comprising:
a substrate including a chip region and a scribe lane region around the chip region, the scribe lane region including an inner boundary in contact with the chip region, and an outer boundary spaced apart from the inner boundary;
a first key region located in the scribe lane region, and spaced apart from the outer boundary of the scribe lane region in a first direction perpendicular to a direction in which the inner boundary of the scribe lane region extends; and
a plurality of division-inducing structures, at least one of which is located between the outer boundary of the scribe lane region and the first key region and is arranged along a second direction intersecting the first direction.

2. The semiconductor device according to claim 1, wherein the division-inducing structures are spaced apart from each other in the first direction.

3. The semiconductor device according to claim 1, further comprising a second key region including a side in contact with the outer boundary,
wherein the second key region is spaced apart from the first key region in the second direction.

4. The semiconductor device according to claim 3, wherein the second key region is spaced apart from the division-inducing structures in the second direction.

5. The semiconductor device according to claim 3, wherein at least another one of the division-inducing structures is located between the first key region and the second key region.

6. The semiconductor device according to claim 3, wherein the division-inducing structures are arranged along an edge of the second key region.

7. The semiconductor device according to claim 1, wherein the division-inducing structures include a dummy gate electrode located on the substrate.

8. The semiconductor device according to claim 1, further comprising a first key group located in the first key region,
wherein the division-inducing structures face the first key group in the first direction.

9. The semiconductor device according to claim 8, wherein a distance between an upper end of each of the division-inducing structures and the substrate is equal to or greater than a distance between an upper end of the first key group and the substrate.

10. The semiconductor device according to claim 1, wherein the division-inducing structures are connected to the substrate.

11. A semiconductor device comprising:
a substrate including a chip region and a scribe lane region around the chip region, the scribe lane region including an inner boundary in contact with the chip region, and an outer boundary spaced apart from the inner boundary;
a first key region located in the scribe lane region, and spaced apart from the outer boundary in a first direction perpendicular to a direction in which the inner boundary extends;
a second key region spaced apart from the first key region in a second direction intersecting the first direction; and
division-inducing structures arranged between the outer boundary and the first key region, or between the first key region and the second key region, or between the outer boundary and the first key region and between the first key region and the second key region.

12. The semiconductor device according to claim 11, wherein the division-inducing structures are spaced apart from each other in the first direction.

13. The semiconductor device according to claim 11, wherein a length of each of the division-inducing structures in the second direction is greater than a length of the corresponding division-inducing structure in the first direction.

14. The semiconductor device according to claim 11, wherein the division-inducing structures are arranged along an edge of the second key region.

15. The semiconductor device according to claim 11, wherein the second key region is spaced apart from the division-inducing structures in the second direction.

16. The semiconductor device according to claim 11, further comprising a first key group located in the first key region,
wherein the division-inducing structures face the first key group in the first direction.

17. A semiconductor device comprising:
a substrate including a chip region and a scribe lane region around the chip region;
a first key region located in the scribe lane region, and including a first boundary facing the chip region, and a second boundary oriented parallel to the first boundary and spaced apart from the first boundary in a first direction perpendicular to a direction in which the first boundary extends; and
division-inducing structures located outside the second boundary in the first direction.

18. The semiconductor device according to claim 17, wherein the division-inducing structures are arranged in a second direction intersecting the first direction.

19. The semiconductor device according to claim 17, further comprising a second key region spaced apart from the first key region in a second direction intersecting the first direction,
wherein the second key region is located to overlap with the division-inducing structures in the second direction.

20. The semiconductor device according to claim 19, wherein the division-inducing structures are located between the first key region and the second key region.

21. A semiconductor device comprising:
a substrate including a scribe lane region adjacent to a chip region;
a first key region located in the scribe lane region including a first key group;
a second key region spaced apart from the first key region; and
a plurality of division-inducing structures spaced apart from each other in a region between the first key region and the second key region,
wherein a length of each of the division-inducing structures in a second direction is greater than a length of in the first direction,
and wherein at least one of the division-inducing structures face the first key group in the first direction.
